(19) United States
(12) Patent Application Publication
(10) Pub. No.: US 2010/0025864 A1
(43) Pub. Date: Feb. 4, 2010

(54) SHIELDED WIREBOND

(75) Inventors: Mark J. Bailey, Lake City, MN (US); Gerald K. Bartley, Rochester, MN (US); Darryl J. Becker, Rochester, MN (US); Paul E. Dahlen, Rochester, MN (US); Philip R. Germann, Oronoco, MN (US); Andrew B. Maki, Rochester, MN (US); Mark O. Maxson, Mantorville, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/183,483

(22) Filed: Jul. 31, 2008

(51) Int. Cl. H01L 23/49; H01L 21/31

(52) U.S. Cl. 257/784; 438/763; 257/E23.049; 257/E21.249

(57) ABSTRACT

A wirebond interconnect structure, having ground pads and signal pads, to which wirebonds are electrically coupled, disposed on a component, is provided and includes a first coating to insulate at least the wirebonds and the signal pads with at least the ground pads exposed, and a second coating, surrounding the first coating, in electrical communication with the ground pads. The first coating is sufficiently thick to achieve a consistent characteristic impedance when the second coating is applied.

### BACKGROUND

Aspects of the present invention are directed to a shielded wirebond and, more particularly, to a wirebond interconnect structure and a method of forming a shielded wirebond interconnect structure.

As cost pressures have continued to drive innovation in component manufacturing technologies, wirebond interconnect structures have become desirable as a less expensive alternative to flip-chip assemblies. However, there are several challenges associated with using wirebond technologies in current components. These challenges relate to the ability of a manufacturer to increase the density of wirebond interconnections. Typically, the ability to densely pack wirebond interconnections is important as designers wish to bring more signals off-chip.

One solution to allow for densely packed wirebond interconnections has been to use insulated wirebonds. Here, the wirebonds are coated with an insulating material, which allows the wirebonds to cross or touch one another. Theoretically, a manufacturer of insulated wirebonds could place the wirebonds very close together and benefit from reduced inductance and overall improved signal-to-reference affinity.

A problem exists, however, in that, even where the insulated wirebonds are placed close together in a formation that lowers their general characteristic loop inductance, the overall structure does not yield a consistent impedance match across the wirebonds with, e.g., transmission structures on a package to which they connect. A further problem exists in that the placing of pairs of wires close together can result in a significant increase in crosstalk between wirebonds.

### SUMMARY

In accordance with an aspect of the invention, a wirebond interconnect structure, having ground pads and signal pads, to which wirebonds are electrically coupled, disposed on a component, is provided and includes a first coating to insulate at least the wirebonds and the signal pads with at least the ground pads exposed, and a second coating, surrounding the first coating, in electrical communication with the ground pads, wherein the first coating is sufficiently thick to achieve a consistent characteristic impedance when the second coating is applied.

In accordance with an aspect of the invention, a wirebond interconnect structure is provided and includes a component, on which ground pads and signal pads are disposed, wirebonds, which are electrically coupled to the signal pads, a first coating to insulate at least the wirebonds and the signal pads with at least the ground pads exposed, and a second coating, surrounding the first coating, in electrical communication with the ground pads, wherein the first coating is sufficiently thick to achieve a consistent characteristic impedance when the second coating is applied.

In accordance with an aspect of the invention, a method of forming a wirebond interconnect structure, having ground pads and signal pads, to which wirebonds are electrically coupled, disposed on a component, is provided and includes masking the ground pads, applying a first coating to insulate at least the wirebonds and the signal pads and to have a pre-selected thickness, unmasking the ground pads, and applying a second coating to surround the first coating and to be in electrical communication with the ground pads, wherein the pre-selected thickness is sufficient to achieve a consistent characteristic impedance when the second coating is applied.

### BRIEF DESCRIPTIONS OF THE SEVERAL VIEWS OF THE DRAWINGS

The subject matter regarded as the invention is particularly pointed out and distinctly claimed in the claims at the conclusion of the specification. The foregoing and other aspects, features, and advantages of the invention are apparent from the following detailed description taken in conjunction with the accompanying drawings in which:

FIG. 1 is a side view of an exemplary wirebond interconnect structure;

FIG. 2 is a side view of the wirebond interconnect structure of FIG. 1 on which a first coating has been applied;

FIG. 3 is a side view of the wirebond interconnect structure of FIGS. 1 and 2 on which a second coating has been applied in accordance with an embodiment of the invention;

FIG. 4 is a side view of the wirebond interconnect structure of FIGS. 1 and 2 on which a second coating has been applied in accordance with another embodiment of the invention; and

FIG. 5 is a flow diagram illustrating an exemplary method of forming a wirebond interconnect structure in accordance with an embodiment of the invention.

### DETAILED DESCRIPTION

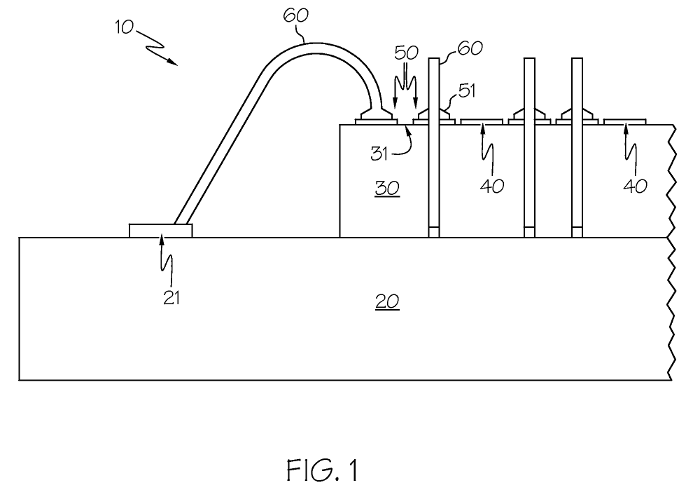

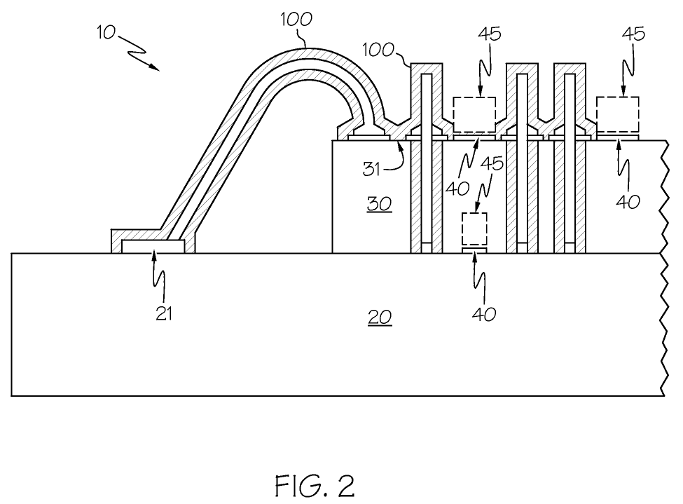

With reference to FIGS. 1-4, in accordance with aspects of the invention, a wirebond interconnect structure 10 is provided. The wirebond interconnect structure 10 includes a substrate 20 on which a component 30 is positioned. Substrate pads 21 (shown only once in FIGS. 1-4 for purposes of clarity) and ground pads 40 are arrayed on the substrate 20. Additional ground pads 40 and signal pads 50 are disposed on a surface 31 of the component 30. Wirebonds 60 connect the substrate pads 21 of the substrate 20 to the signal pads 50. With this configuration, the substrate 20 may include any number of chip carrier technologies, or a printed circuit board (PCB). The component 30 may include an electrical component, such as a microprocessor. The wirebonds 60 are coupled to the signal pads 50 by a bonding agent 51, such as solder material, and are configured to transmit signals outputted by the component 30 to external devices.

A first coating 100 is applied to the wirebonds 60 and the signal pads 50 with the ground pads 40 exposed. The first coating 100 serves to insulate the wirebonds 60 and the signal pads 50 from short-circuits which would otherwise occur between pairs or more of the wirebonds 60. In addition, the first coating 100 is applied to have a thickness that is sufficient to achieve a consistent characteristic impedance when a second coating 200 is applied. The second coating 200 is applied to surround the first coating 100 and to be in electrical connection with the ground pads 40 on the substrate 20 and the component 30.

In accordance with various embodiments of the invention, the first coating 100 may include any one or more of an insulating material, an insulative conformal coating, a silicone-based conformal coating, other suitable coatings and/or combinations thereof. Here, the silicone-based conformal coating may be particularly useful due to its process versatility that arises from its useful temperature range, applicability, flexibility and stress relief. The application of the first coating 100 may be achieved by various methods including, but not limited to, spray coating, dip coating and/or any other suitable methods.

Since the wirebond interconnect structure 10 may be seen as a coaxial structure, it follows that the characteristic impedance of the wirebonds 60 is a function of the thickness of the first coating 100. The thickness is generally controlled by regulating the output of the material of the first coating 100 at a flow valve from which the first coating 100 is ejected during an application thereof. A viscosity of a material of the first coating 100 will place an upper limit on the thickness and, in an embodiment of the invention, a single application could result in a thin layer with a low impedance. Meanwhile, in order to provide for additional impedance control, multiple applications of the first coating 100 can be undertaken to engineer different impedance values thereof.

Various application methods for the first coating 100 are possible. In a first method, a base process of using a thin, single layer of dielectric material is applied to insulate the wirebonds 60. In a second method, a more complex process is conducted. Here, multiple applications of the dielectric material build up the thickness of the first coating 100 and subsequently leads to the desired impedance. Of course, other methods of applying the first coating 100 are possible and within the scope of this application.

In detail, for a 1 mm diameter unshielded wirebond with a 1 mm pitch, characteristic impedance is about 120 ohms. In contrast, when the wirebond is provided with a 1-mil thick first coating 100 and a shielding material such as the second coating 200 around it, the impedance lowers to 38 ohms.

The ground pads 40 are prevented from being coated by the first coating 100 by the mask 45 which is positioned over the ground pads 40 of the component 30 and the substrate 20 before the application of the first coating 100 and which is removed from the ground pads 40 once the application of the first coating 100 is complete. The mask 45 may be a mask that reflects the overall configuration of the ground pads 40 relative to the surface 31 of the component 30, the signal pads 50 and the wirebonds 60. In another embodiment, the mask 45 may be plural in number and individually attachable to each of the ground pads 40.

The second coating 200 may include any one or more of an electrically conductive coating, an electrically conductive coating that includes particulate fillings, an electrically conductive conformal coating, an electrically conductive non-conformal coating, other suitable coatings and/or combinations thereof. Where the second coating 200 includes the electrically conductive coating that includes particulate fillings, the second coating 200 can be one of several known polymer systems, such as nickel-impregnated “E-coat,” or a conductor-impregnated epoxy.

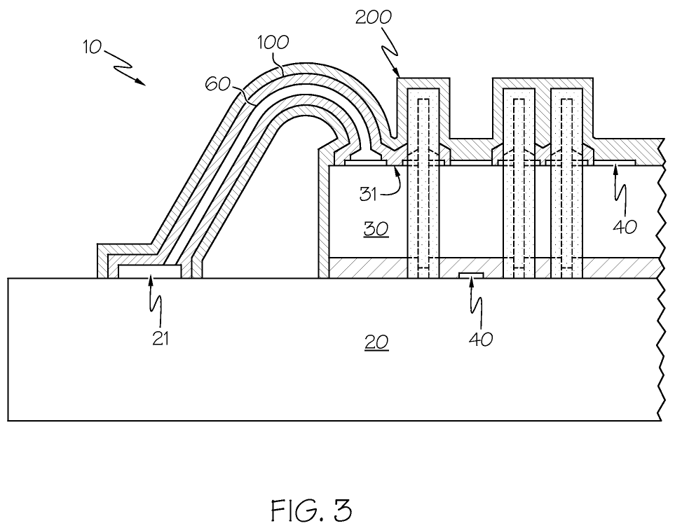

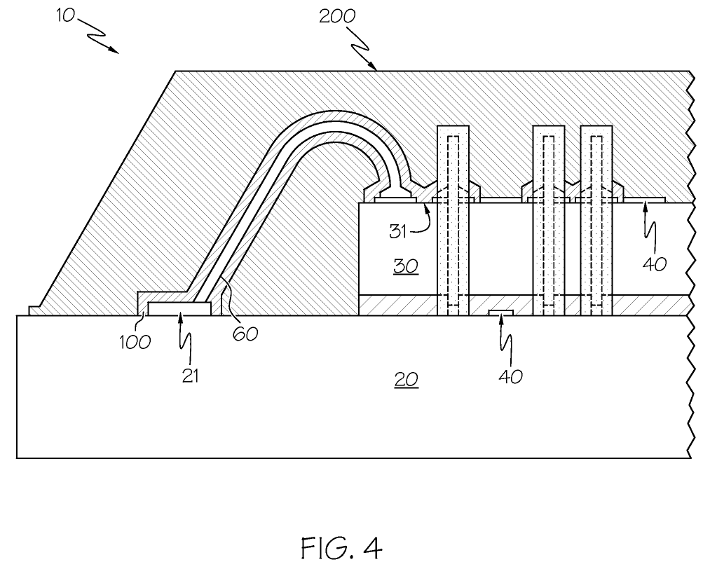

As shown in FIG. 3, the second coating 200 may be formed with a shape that conforms to that of the other components discussed herein. In an alternate embodiment shown in FIG. 4, the second coating 200 may be formed with a shape that does not conform to the other components discussed herein. Whether the second coating 200 has a conforming shape or a non-conforming shape can be determined by the manufacturer based on various considerations such as costs and machining tolerances.

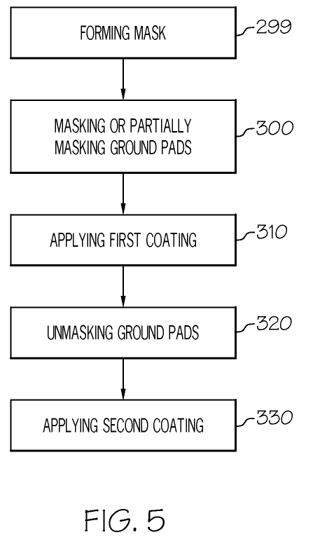

With reference to FIG. 5, in accordance with another aspect of the invention, a method of forming a wirebond interconnect structure 10, having ground pads 40 and signal pads 50, to which wirebonds 60 are electrically coupled, disposed on a component 20, is provided. The method includes masking the ground pads 40 (operation 300), and applying a first coating 100 (operation 310) to insulate at least the wirebonds 60 and the signal pads 50 and to have a thickness that is sufficient to achieve a consistent characteristic impedance when a second coating 200 is applied. The method further includes unmasking the ground pads 40 (operation 320), and applying a second coating 200 to surround the first coating 100 and to be in electrical communication with the ground pads 40 (operation 330).

Here, the masking of the ground pads 40 may include forming a mask that is reflective of positions, shapes and sizes of the ground pads 40 with respect to the component 30 and, more particularly, the surface 31 of the component 30 (operation 299). Also, the masking of the ground pads 40 may include only a partial masking of the ground pads 40 such that portions of the ground pads 40 are allowed to come into contact with the first coating 100. This may reduce a cost of having to unnecessarily precisely deposit the first coating 100.

In addition, it is noted that the applying of the first coating 100 includes regulating an output of a material of the first coating 100 through a flow valve therefore. The applying of the first coating further includes spray coating and/or dip coating the first coating onto the wirebonds 60 and the signal pads 50 and/or applying a first layer of the first coating 100 to insulate the wirebonds 60 and the signal pads 50, and applying additional layers of the first coating 100 to achieve the characteristic impedance matching. The applying of the second coating 200, on the other hand, may include either applying the second coating 200 to conformally surround the first coating 100 or to non-conformally surround the first coating 100.

In accordance with the wirebond interconnect structures 10 and methods of forming the same, as discussed above, it is seen that a manufacturer can reduce crosstalk in and amongst the wirebonds 60 and thereby improve an impedance performance thereof. Moreover, since the second coating 200 is grounded, as is described above, the resulting wirebond interconnect structures 10 may be seen as being essentially coaxial.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular exemplary embodiment disclosed as the best mode contemplated for carrying out this disclosure, but that the disclosure will include all embodiments falling within the scope of the appended claims.

What is claimed is:

1. A wirebond interconnect structure, having ground pads and signal pads, to which wirebonds are electrically coupled, disposed on a component, the structure comprising:
a first coating to insulate at least the wirebonds and the signal pads with at least the ground pads exposed; and
a second coating, surrounding the first coating, in electrical communication with the ground pads, wherein the first coating is sufficiently thick to achieve a consistent characteristic impedance when the second coating is applied.

2. The structure according to claim 1, wherein the first coating comprises insulating material.

3. The structure according to claim 1, wherein the first coating comprises an insulative conformal coating.

4. The structure according to claim 1, wherein the first coating comprises a silicone-based conformal coating.

5. The structure according to claim 1, wherein the second coating comprises an electrically conductive coating.

6. The structure according to claim 5, wherein the electrically conductive coating comprises a coating with particulate fillings.

7. The structure according to claim 1, wherein the second coating comprises an electrically conductive conformal coating.

8. The structure according to claim 1, wherein the second coating comprises an electrically conductive non-conformal coating.

9. A wirebond interconnect structure comprising:
a component, on which ground pads and signal pads are disposed;
wirebonds, which are electrically coupled to the signal pads;
a first coating to insulate at least the wirebonds and the signal pads with at least the ground pads exposed; and
a second coating, surrounding the first coating, in electrical communication with the ground pads, wherein the first coating is sufficiently thick to achieve a consistent characteristic impedance when the second coating is applied.

10. A method of forming a wirebond interconnect structure, having ground pads and signal pads, to which wirebonds are electrically coupled, disposed on a component, the method comprising:
masking the ground pads;
applying a first coating to insulate at least the wirebonds and the signal pads and to have a pre-selected thickness;
unmasking the ground pads; and
applying a second coating to surround the first coating and to be in electrical communication with the ground pads, wherein the pre-selected thickness is sufficient to achieve a consistent characteristic impedance when the second coating is applied.

11. The method according to claim 10, wherein the masking of the ground pads comprises forming a mask that is reflective of positions, shapes and sizes of the ground pads with respect to the component.

12. The method according to claim 10, wherein the masking of the ground pads comprises a partial masking of the ground pads.

13. The method according to claim 10, wherein the applying of the first coating comprises regulating an output of a material of the first coating through a flow valve therefore.

14. The method according to claim 10, wherein the applying of the first coating comprises spray coating the first coating onto the wirebonds and the signal pads.

15. The method according to claim 10, wherein the applying of the first coating comprises dip coating the first coating onto the wirebonds and the signal pads.

16. The method according to claim 10, wherein the applying of the first coating comprises:
applying a first layer of the first coating to insulate the wirebonds and the signal pads; and
applying additional layers of the first coating to achieve the characteristic impedance matching.

17. The method according to claim 10, wherein the applying of the second coating comprises applying the second coating to conformally surround the first coating.

18. The method according to claim 10, wherein the applying of the second coating comprises applying the second coating to non-conformally surround the first coating.
